(19) United States
(12) Patent Application Publication
(10) Pub. No.: US 2019/0386053 A1
(43) Pub. Date: Dec. 19, 2019

(54) SEMICONDUCTOR DEVICE AND MANUFACTURING METHOD OF SEMICONDUCTOR DEVICE

(71) Applicant: SONY SEMICONDUCTOR SOLUTIONS CORPORATION, KANAGAWA (JP)

(72) Inventor: SHIGEKI AMANO, TOKYO (JP)

(21) Appl. No.: 16/480,512

(22) PCT Filed: Dec. 26, 2017
(86) PCT No.: PCT/JP2017/046637

§ 371 Date: Jul. 24, 2019

(30) Foreign Application Priority Data
Feb. 9, 2017 (JP) 2017-021853

(51) Int. Cl. H01L 27/146

(52) U.S. Cl. CPC H01L 27/14634; H01L 27/1469; H01L 27/14636; H01L 27/14618

(57) ABSTRACT

To provide a semiconductor device in which a terminal for outputting an electric signal to outside is further miniaturized, and a manufacturing method of the semiconductor device. A semiconductor device provided with a first chip formed by stacking a first substrate and a first wiring layer, the first chip including a sensor element, a second chip formed by stacking a second substrate and a second wiring layer, the second chip bonded to the first chip such that the first wiring layer faces the second wiring layer, and at least one or more through-hole vias electrically connected to the second wiring layer and penetrating the second substrate to protrude from a surface of the second chip opposed to a surface on which the first chip is stacked.

### TECHNICAL FIELD

The present disclosure relates to a semiconductor device and a manufacturing method of the semiconductor device.

### BACKGROUND ART

In recent years, with downsizing of various semiconductor elements, downsizing of packages on which the various semiconductor elements are mounted is also advanced.

For example, a wafer level chip scale package (WLCSP) which is made more compact by making an area of the package (in other words, a peripheral unit) substantially the same as an area of a semiconductor chip is suggested.

In such WLCSP, wiring by a bonding wire or the like to an external terminal formed on an outer periphery of the package is not performed, and a bump structure to be an external connecting terminal is directly formed on a back surface of the semiconductor chip.

For example, following Patent Document 1 discloses forming an extraction electrode electrically connected to a wiring layer of a pixel array by providing an opening on a back surface of a device substrate after forming the pixel array on a front surface of the device substrate in a semiconductor image sensor.

### CITATION LIST

### Patent Document

Patent Document 1: Japanese Patent Application Laid-Open No. 2010-199589

### SUMMARY OF THE INVENTION

### Problems to be Solved by the Invention

However, in the technology disclosed in Patent Document 1, when providing the opening on the back surface of the device substrate, it is necessary to align the wiring layer provided inside the device substrate with the opening, so that it is required to form the opening larger in consideration of an alignment error. Therefore, in the technology disclosed in Patent Document 1, there is a limit in miniaturization of the electrode or the terminal for extracting an electric signal from the device substrate.

Therefore, in the present disclosure, novel and improved semiconductor device and manufacturing method of the semiconductor device capable of more minutely forming the terminal which extracts the electric signal from the chip on which various semiconductor elements are mounted.

### Solutions to Problems

According to the present disclosure, provided is a semiconductor device provided with a first chip formed by stacking a first substrate and a first wiring layer, the first chip including a sensor element, a second chip formed by stacking a second substrate and a second wiring layer, the second chip bonded to the first chip such that the first wiring layer faces the second wiring layer, and at least one or more through-hole vias electrically connected to the second wiring layer and penetrating the second substrate to protrude from a surface of the second chip opposed to a surface on which the first chip is stacked.

Furthermore, according to the present disclosure, provided is a manufacturing method of a semiconductor device provided with: a step of forming a first chip including a sensor element by stacking a first substrate and a first wiring layer; a step of forming a second chip by stacking a second substrate and a second wiring layer; a step of forming at least one or more through-hole vias electrically connecting to the second wiring layer and stretching in a thickness direction of the second substrate; and a step of bonding the first chip to the second chip such that the first wiring layer faces the second wiring layer.

According to the present disclosure, since a terminal for connecting to the outside may be formed in advance on the chip on which the semiconductor device is mounted by using a manufacturing process of the semiconductor element, the terminal for outputting the electric signal from the semiconductor device to the outside may be more minutely formed.

### Effects of the Invention

As described above, according to the present disclosure, it is possible to more minutely form the terminal for extracting the electric signal from the chip on which various elements are mounted.

Note that the above-described effect is not necessarily limited, and it is also possible to obtain any one of the effects described in this specification or another effect which may be grasped from this specification together with or in place of the above-described effect.

### BRIEF DESCRIPTION OF DRAWINGS

FIG. 1 is a cross-sectional view schematically illustrating a cross-section obtained by cutting a semiconductor device according to one embodiment of the present disclosure in a thickness direction.

FIG. 2 is an enlarged cross-sectional view of a region including a through-hole via of FIG. 1.

FIG. 3 is a cross-sectional view for illustrating one step of a first manufacturing method of the semiconductor device according to this embodiment.

FIG. 4 is a cross-sectional view for illustrating one step of the first manufacturing method of the semiconductor device according to this embodiment.

FIG. 5 is a cross-sectional view for illustrating one step of the first manufacturing method of the semiconductor device according to this embodiment.

FIG. 6 is a cross-sectional view for illustrating one step of the first manufacturing method of the semiconductor device according to this embodiment.

FIG. 7 is a cross-sectional view for illustrating one step of the first manufacturing method of the semiconductor device according to this embodiment.

FIG. 8 is a cross-sectional view illustrating a second chip without a second element unit provided.

FIG. 9 is a cross-sectional view illustrating a configuration in which the second chip illustrated in FIG. 8 is bonded to the first chip.

FIG. 10 is a cross-sectional view for illustrating one step of a second manufacturing method of the semiconductor device according to this embodiment.

FIG. 11 is a cross-sectional view for illustrating one step of the second manufacturing method of the semiconductor device according to this embodiment.

FIG. 12 is a cross-sectional view for illustrating one step of the second manufacturing method of the semiconductor device according to this embodiment.

### MODE FOR CARRYING OUT THE INVENTION

A preferred embodiment of the present disclosure is hereinafter described in detail with reference to the accompanying drawings. Note that, in this specification and the drawings, the components having substantially the same functional configuration are assigned with the same reference sign, and the description thereof is not repeated.

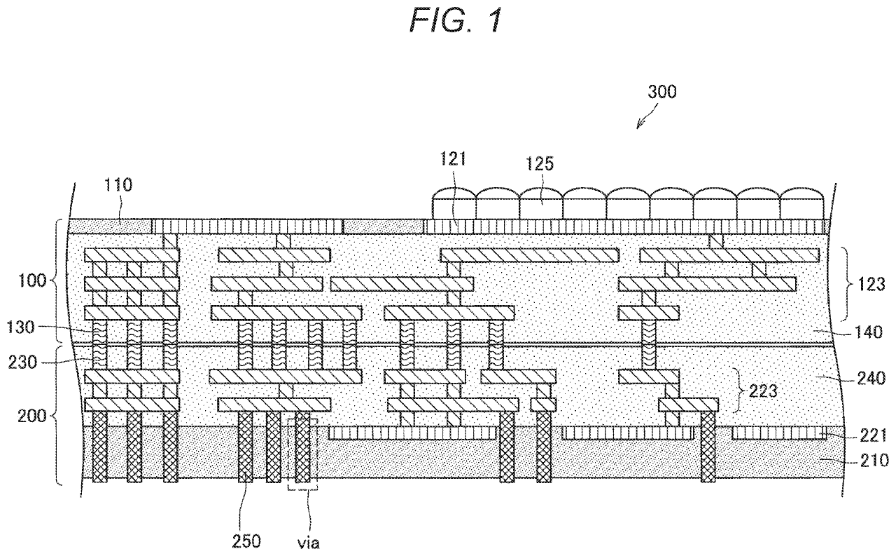

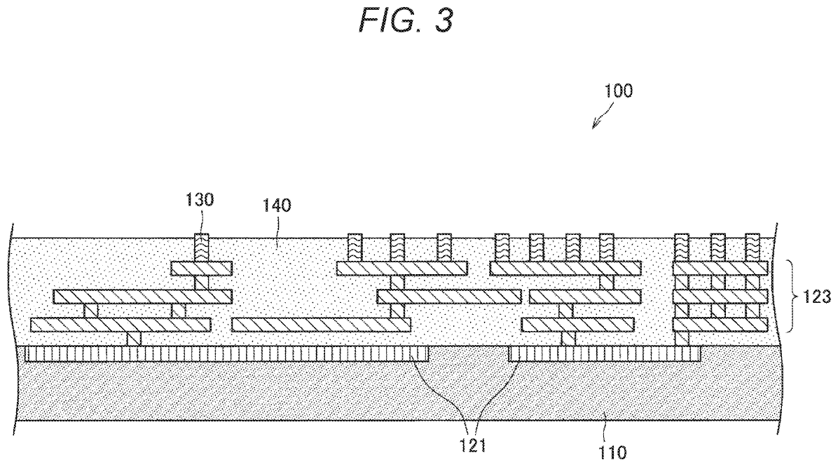

In this specification, for convenience of description, in a case where a semiconductor device 300 is described (FIGS. 1, 2, 5 to 7, and 9 to 12), a side on which a second substrate 210 is provided is expressed as a lower side. Furthermore, in a case where only a first chip 100 or a second chip 200 is described (FIGS. 3, 4, and 8), a side on which a first substrate 110 or a second substrate 210 is provided is expressed as a lower side.

Note that, the description is given in the following order.

1. Configuration of Semiconductor Device

2. Manufacturing Method of Semiconductor Device

2.1. First Manufacturing Method

2.2. Second Manufacturing Method

3. Summary

<1. Configuration of Semiconductor Device>

First, a configuration of a semiconductor device according to one embodiment of the present disclosure is described with reference to FIG. 1. FIG. 1 is a cross-sectional view schematically illustrating a cross-section obtained by cutting the semiconductor device according to one embodiment of the present disclosure in a thickness direction.

As illustrated in FIG. 1, a semiconductor device 300 is a stacked semiconductor device obtained by bonding a first chip 100 provided with a first element unit 121 including a sensor element to a second chip 200. Furthermore, the sensor element included in the semiconductor device 300 may be a solid-state imaging element such as an image sensor. In other words, the semiconductor device 300 according to this embodiment may be a stacked solid-state imaging device, and especially may be a back illuminated solid-state imaging device.

(First Chip 100)

The first chip 100 is a semiconductor chip including at least the sensor element in which a first wiring layer including a multilayer wiring layer 123 and an interlayer insulating film 140 is stacked on a first substrate 110.

The first chip 100 is provided with the first substrate 110, the first element unit 121 formed on the first substrate 110, an optical element 125 formed on a surface of the first substrate 110, the multilayer wiring layer 123 electrically connected to the first element unit 121, the interlayer insulating film 140 in which the multilayer wiring layer 123 is embedded, and a connecting terminal 130 electrically connected to the multilayer wiring layer 123. Note that the first chip 100 is bonded to the second chip 200 so that the interlayer insulating film 140 faces an interlayer insulating film 240 of the second chip 200.

The first substrate 110 is a substrate in which the first element unit 121 is formed. Specifically, the first substrate 110 may be a semiconductor substrate in which a semiconductor element may be easily formed. For example, the first substrate 110 may be a semiconductor substrate such as a silicon (Si) substrate, a germanium (Ge) substrate, or a silicon-germanium (SiGe) substrate.

The first element unit 121 is formed by using a semiconductor element and executes substantial functions of the semiconductor device 300. Specifically, the first element unit 121 may be formed by using the semiconductor elements such as various diodes and various transistors. Furthermore, the first element unit 121 includes at least the sensor element. The sensor element may be, for example, a complementary metal-oxide-semiconductor (CMOS) image sensor, a charge-coupled device (CCD) image sensor, or a photo diode. Moreover, the first element unit 121 may include an integrated circuit such as a signal processing circuit which processes a signal from the sensor element or a control circuit.

The optical element 125 is provided in a case where the sensor element included in the first element unit 121 is the image sensor or the like. Specifically, the optical element 125 is provided on one surface of the first substrate 110 on a region in which the first element unit 121 is provided, and optically controls incident light on the sensor element included in the first element unit 121.

For example, the optical element 125 may include a microlens for condensing the incident light on the sensor element, a color filter for color separation of the incident light on the sensor element, a pixel separating film or a light shielding film for preventing incidence of the light on other than the sensor element, a protecting layer which protects them, and the like. By providing the optical element 125, the semiconductor device 300 may improve performance as the solid-state imaging device such as resolution and color resolution.

The multilayer wiring layer 123 is provided on the other surface opposed to one surface on which the optical element 125 is provided of the first substrate 110. Specifically, the multilayer wiring layer 123 is formed by stacking a plurality of layers of the wires provided in the same layer and vias electrically connecting the wires provided in different layers on the first substrate 110. Furthermore, the multilayer wiring layer 123 is electrically connected to the first element unit 121 and extracts an electric signal from the first element unit 121. For example, the multilayer wiring layer 123 may extract, from the first element unit 121, the electric signal generated by photoelectric conversion of the incident light by the sensor element (for example, the CMOS image sensor) included in the first element unit 121. The multilayer wiring layer 123 may be formed by using, for example, metal such as aluminum, copper, or silver being a conductor, an alloy of the metal, or silicide.

The interlayer insulating film 140 is provided on the other surface opposed to one surface on which the optical element 125 is provided of the first substrate 110, and electrically insulates each layer of the multilayer wiring layer 123 by embedding the multilayer wiring layer 123 therein. Specifically, the interlayer insulating film 140 electrically insulates the wires provided in each layer of the multilayer wiring layer 123 by embedding each of the wires and the vias of the multilayer wiring layer 123 for each layer. Furthermore, the interlayer insulating film 140 may also improve mechanical strength of the first chip 100. The interlayer insulating film 140 may be formed by using, for example, a silicon compound such as silicon oxide, silicon nitride, or silicon oxynitride, inorganic glass such as spin-on glass or silicate glass, an organic compound such as polyimide or polyamide, or the like.

The connecting terminal 130 is provided so as to protrude from the interlayer insulating film 140, and forms an interface for inputting and outputting the electric signal between the first chip 100 and the second chip 200. Specifically, the connecting terminal 130 is electrically connected to the multilayer wiring layer 123, and extracts the electric signal from the first element unit 121 out of the first chip 100 via the multilayer wiring layer 123. Furthermore, the connecting terminal 130 is electrically connected to a connecting terminal 230 of the second chip 200 by metal-metal bonding or the like, and outputs the electric signal from the first element unit 121 to the second chip 200. The connecting terminal 130 may be formed by using, for example, metal such as aluminum, copper, silver, gold, or platinum being a conductor, or an alloy of the metal.

Note that a plurality of connecting terminals 130 may be provided for the same signal line of the multilayer wiring layer 123. By providing the plurality of connecting terminals 130 for the same signal line, even in a case where a connection failure occurs in any of the connecting terminals 130, another connecting terminal 130 may output the electric signal to the second chip 200. In such a case, the connecting terminal 130 may improve reliability of electric connection with the connecting terminal 230.

(Second Chip 200)

The second chip 200 is a semiconductor chip in which a second wiring layer including a multilayer wiring layer 223 and an interlayer insulating film 240 is stacked on the second substrate 210.

The second chip 200 is provided with the second substrate 210, a second element unit 221 formed in the second substrate 210, the multilayer wiring layer 223 electrically connected to the second element unit 221, the interlayer insulating film 240 in which the multilayer wiring layer 223 is embedded, a plurality of through-hole vias 250 penetrating the second substrate 210, and the connecting terminal 230 electrically connected to the multilayer wiring layer 223. Note that the second chip 200 is bonded to the first chip 100 so that the interlayer insulating film 240 faces the interlayer insulating film 140 of the first chip 100.

The second substrate 210 is a substrate in which the through-hole vias 250 to be external connecting terminals of the semiconductor device 300 are formed. Specifically, the second substrate 210 may be a semiconductor substrate in which the semiconductor element may be easily formed. For example, the second substrate 210 may be a semiconductor substrate such as a silicon (Si) substrate, a germanium (Ge) substrate, or a silicon-germanium (SiGe) substrate. Note that the second substrate 210 may be formed by using the same material as that of the first substrate 110 or may be formed by using a different material.

The second element unit 221 is an element or a circuit formed by using a semiconductor element. For example, the second element unit 221 may be an active element electrically connected to the first element unit 121. More specifically, the second element unit 221 may be an arithmetic processing circuit such as a micro processing unit (MPU) which controls the first element unit 121, and a storage element such as a dynamic random access memory (DRAM) which stores the electric signal from the first element unit 121, and the like. Note that the second element unit 221 has an arbitrary configuration, and it is possible that this is not provided depending on the configuration of the semiconductor device 300 or the function executed by the semiconductor device 300.

The multilayer wiring layer 223 is provided on a surface facing the first chip 100 of the second substrate 210. Specifically, the multilayer wiring layer 223 is formed by stacking a plurality of layers of wires provided in the same layer and vias electrically connecting the wires provided in different layers on the second substrate 210. Furthermore, the multilayer wiring layer 223 is electrically connected to the multilayer wiring layer 123 of the first chip 100 via the connecting terminal 230, and receives the electric signal output from the first chip 100. Specifically, the multilayer wiring layer 223 may receive the electric signal from the first element unit 121 of the first chip 100, and output the received electric signal to the second element unit 221 or out of the semiconductor device 300. The multilayer wiring layer 223 may be formed by using metal such as aluminum, copper, or silver being a conductor, an alloy of the metal, or silicide. Note that the multilayer wiring layer 223 may be formed by using the same material as the multilayer wiring layer 123, or may be formed by using a different material.

The interlayer insulating film 240 is provided on the surface facing the first chip 100 of the second substrate 210, and electrically insulates each layer of the multilayer wiring layer 223 by embedding the multilayer wiring layer 223 therein. Specifically, the interlayer insulating film 240 electrically insulates the wires provided in each layer of the multilayer wiring layer 223 by embedding each of the wires and the vias of the multilayer wiring layer 223 for each layer. Furthermore, the interlayer insulating film 240 may also improve mechanical strength of the second chip 200. The interlayer insulating film 240 may be formed by using, for example, a silicon compound such as silicon oxide, silicon nitride, or silicon oxynitride, inorganic glass such as spin-on glass or silicate glass, an organic compound such as polyimide or polyamide, or the like. Furthermore, the interlayer insulating film 240 may be formed by using the same material as that of the interlayer insulating film 140, or may be formed by using a different material.

The connecting terminal 230 is provided so as to protrude from the interlayer insulating film 240 in a position corresponding to the connecting terminal 130, and forms the interface for inputting and outputting the electric signal between the first chip 100 and the second chip 200. Specifically, the connecting terminal 230 receives the electric signal from the first element unit 121 and outputs the received electric signal to the electrically connected multilayer wiring layer 223 by electrically connecting to the connecting terminal 130 of the first chip 100 by metal-metal bonding or the like.

The connecting terminal 230 may be formed by using, for example, metal such as aluminum, copper, silver, gold, or platinum being a conductor, or an alloy of the metal. Although the connecting terminal 230 may be formed by using a material different from that of the connecting terminal 130, in order to easily form the metal-metal bonding between the connecting terminal 230 and the connecting terminal 130, the connecting terminal 230 is preferably formed by using the same material as that of the connecting terminal 130.

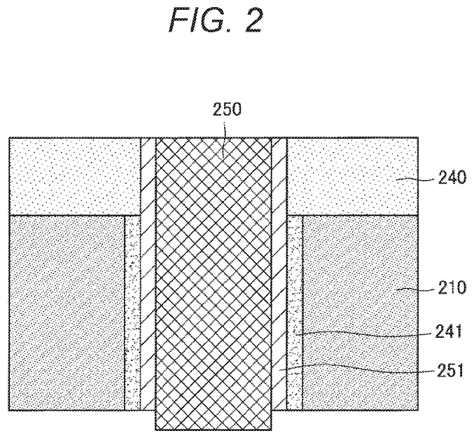

The through-hole via 250 is electrically connected to the multilayer wiring layer 223 and provided so as to penetrate the second substrate 210. Specifically, the through-hole via 250 may also be formed as a filled via with an inside filled with metal or the like. By being formed as the filled via, the through-hole via 250 may increase a cross-sectional area of a conduction path, so that this may improve conductivity when the semiconductor device 300 is mounted. A specific structure of the through-hole via 250 is described later with reference to FIG. 2.

Furthermore, the through-hole via 250 may also be formed such that a cross-sectional area on a first surface in contact with the interlayer insulating film 240 of the second substrate 210 is the same as or larger than a cross-sectional area on a second surface opposed to the first surface. In other words, in a case where a stacking direction of the interlayer insulating film 240 on the second substrate 210 is regarded as an upward direction, the through-hole via 250 may be formed to have an inverted tapered or a rectangular cross-sectional shape (that is, not to have a forward tapered cross-sectional shape).

Such through-hole via 250 may be formed by opening the second substrate 210 and filling the opening with metal or the like before forming the second wiring layer (in other words, the multilayer wiring layer 223 and the interlayer insulating film 240) on the second substrate 210. By thus forming the through-hole via 250 in the second substrate 210 in advance, the through-hole via 250 may be connected to the multilayer wiring layer 223 with high accuracy. In such a case, the through-hole via 250 may be formed with finer arrangement and shape because it is not necessary to consider an alignment error with the multilayer wiring layer 223, and connection accuracy to the multilayer wiring layer 223 may be improved.

Furthermore, by forming the through-hole via 250 having such shape as the filled via, an area of the opening formed on the second substrate 210 may be decreased, so that the mechanical strength of the second chip 200 may be improved.

Moreover, since the through-hole via 250 is formed so as to protrude from the second substrate 210, this may be used as a connection structure (so-called a bump or the like) to the outside when the semiconductor device 300 is mounted on a printed wiring board. Therefore, in the semiconductor device 300 according to this embodiment, a step of separately forming the bump may be omitted, so that productivity of the semiconductor device 300 may be improved. Note that a protruding amount of the through-hole via 250 from the second substrate 210 may be, for example, approximately 1 μm to 9 μm.

Furthermore, by using the through-hole via 250 as the bump, wiring of the wire from the through-hole via 250 to the bump, and the like may also be omitted. With this arrangement, it is possible to decrease the wires or structures provided on a surface on which the connection structure to the outside is formed of the semiconductor device 300, so that the through-hole via 250 may be more flexibly arranged. For example, it is also possible to uniformly arrange the through-hole vias 250 at a fine pitch over an entire surface of the semiconductor device 300.

Note that a plurality of through-hole vias 250 may be provided for the same signal line of the multilayer wiring layer 223. By providing the plurality of through-hole vias 250 for the same signal line, even in a case where the connection failure occurs in any of the through-hole vias 250, it is possible to output the electric signal to the outside by another through-hole via 250. Therefore, in such a case, the through-hole via 250 may improve the reliability of the electric connection of the semiconductor device 300.

Subsequently, a more specific structure of the through-hole via 250 formed in the semiconductor device 300 according to this embodiment is described with reference to FIG. 2. FIG. 2 is an enlarged cross-sectional view of a region via including the through-hole via 250 of FIG. 1.

As illustrated in FIG. 2, a barrier metal layer 251 is provided on a surface of the through-hole via 250, and an insulating layer 241 is provided between the through-hole via 250 and the second substrate 210.

The barrier metal layer 251 is a layer which serves as a barrier so that a material of the through-hole via 250 does not diffuse into the second substrate 210 when the through-hole via 250 is formed. The barrier metal layer 251 is provided on the opening in which the through-hole via 250 is formed before the through-hole via 250 is formed, so that this is present on the surface of the through-hole via 250. The barrier metal layer 251 is formed by using a metal material which does not react with the materials of the through-hole via 250 and the second substrate 210 and has high adhesion to these materials. The barrier metal layer 251 may be formed by using, for example, metal such as tungsten, titanium, or tantalum, an alloy of the metal, or nitride.

According to the barrier metal layer 251, it is possible to suppress the material of the through-hole via 250 from diffusing into the second substrate 210, so that electric insulation between the through-hole via 250 and the second substrate 210 may be improved.

The insulating layer 241 is provided between the through-hole via 250 including the barrier metal layer 251 and the second substrate 210 and electrically insulates the through-hole via 250 from the second substrate 210. Therefore, according to the insulating layer 241, the electric insulation between the through-hole via 250 and the second substrate 210 may be improved, so that leakage of a current from the through-hole via 250 to the second substrate 210 may be prevented.

Here, the insulating layer 241 is preferably formed by using a highly electrically insulating insulator generated by a high-temperature process. The insulator generated by the high-temperature process has higher electric insulation because atomic bonding in the insulator becomes stronger and density of the insulator increases. Therefore, when the insulating layer 241 is formed by using the insulator generated by the high-temperature process, the electric insulation between the through-hole via 250 and the second substrate 210 may be further improved.

Such insulating layer 241 may be formed by using, for example, an oxide formed by thermally oxidizing the second substrate 210, or a silicon compound such as silicon oxide, silicon nitride, or silicon oxynitride vapor-deposited by high-temperature chemical vapor deposition (CVD).

However, in the semiconductor device 300 according to this embodiment, the first element unit 121 includes the sensor element. Since the sensor element is weak against heat, in a case where the sensor element is exposed to high temperature at a manufacturing step of the semiconductor device 300, a characteristic and reliability of the sensor element might be degraded, and in some cases, the sensor element might be broken. Therefore, in the semiconductor device 300 after the sensor element is formed, it is difficult to deposit the insulator by the high-temperature process, so that, in a case where the insulating layer 241 is formed in the semiconductor device 300 after the sensor element is formed, the electric insulation of the insulating layer 241 is lowered.

In the semiconductor device 300 according to this embodiment, the through-hole via 250 is formed in the second substrate 210 in advance, so that the insulating layer 241 between the through-hole via 250 and the second substrate 210 may be formed by using the insulator generated by the high-temperature process. Therefore, the semiconductor device 300 according to this embodiment may further improve the electric insulation between the through-hole via 250 and the second substrate 210.

Furthermore, in the semiconductor device 300 according to this embodiment, the insulating layer 241 between the through-hole via 250 and the second substrate 210 is formed by using the insulator generated by the high-temperature process, so that a film thickness of the insulating layer 241 may be made uniform as compared with that by other processes. In such a case, local electric field concentration hardly occurs in the insulating layer 241, so that the semiconductor device 300 may suppress occurrence of insulation breakdown or a leak current due to the local electric field concentration.

Moreover, in the semiconductor device 300 according to this embodiment, since the through-hole via 250 is formed in advance in the second substrate 210, the connection structure to the outside may be formed in an arbitrary position of the semiconductor device 300. With this arrangement, the semiconductor device 300 may more flexibly change the number and arrangement of the connection structures with the outside.

<2. Manufacturing Method of Semiconductor Device>

(2.1. First Manufacturing Method)

Here, with reference to FIGS. 3 to 7, a first manufacturing method of the semiconductor device according to this embodiment is described. FIGS. 3 to 7 are cross-sectional views for illustrating each step of the first manufacturing method of the semiconductor device according to this embodiment.

First, as illustrated in FIG. 3, the first chip 100 is prepared.

Specifically, the first element unit 121 is formed in the first substrate 110 which is the silicon substrate by using a semiconductor manufacturing process. Thereafter, the multilayer wiring layer 123 and the interlayer insulating film 140 are formed on the first substrate 110 on which the first element unit 121 is formed, by using CVD, sputtering, plating or the like. Furthermore, the connecting terminal 130 is further formed on an uppermost multilayer wiring layer 123. With this arrangement, the first chip 100 is formed. Note that the multilayer wiring layer 123 and the connecting terminal 130 may be formed by using copper or the like. Furthermore, the interlayer insulating film 140 may be formed by using silicon oxide, silicon nitride, or the like.

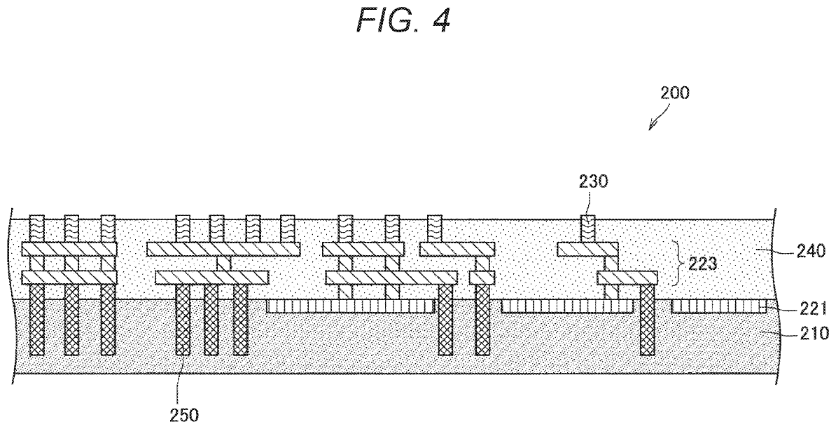

Next, as illustrated in FIG. 4, the second chip 200 is prepared.

Specifically, the second element unit 221 is formed in the second substrate 210 which is the silicon substrate using the semiconductor manufacturing process. Next, one layer of the interlayer insulating film 240 is formed on the second substrate 210, and then etching is performed to form the opening for forming the through-hole via 250 in the second substrate 210.

The arrangement of the opening formed at that time is the arrangement of the external connecting terminal of the semiconductor device 300. Therefore, the opening may be formed in the arrangement corresponding to the position of the terminal of the printed wiring board on which the semiconductor device 300 is mounted, while avoiding a region in which the second element unit 221 is formed. Furthermore, the opening of the second substrate 210 may be formed by isotropic etching. By using the isotropic etching, the opening provided in the second substrate 210 is formed in a columnar shape or an inverse tapered shape with respect to the second substrate 210.

Subsequently, the insulating layer 241 is formed within the opening formed in the second substrate 210. The insulating layer 241 is formed by a high-temperature semiconductor manufacturing process in order to further improve the electric insulation. For example, the insulating layer 241 may be formed by thermal oxidation of the second substrate 210 or deposition of silicon oxide.

Next, the barrier metal layer 251 is uniformly formed on the entire surface of the second substrate 210 using sputtering, and then a seed layer formed by using copper is formed on the barrier metal layer 251 using sputtering. Moreover, by growing the seed layer by electrolytic plating, the opening formed in the second substrate 210 is filled with copper, and the through-hole via 250 is formed. Thereafter, the barrier metal layer and the seed layer formed on the surface of the second substrate 210 are removed by chemical mechanical polish (CMP) or the like. With this arrangement, the through-hole via 250 may be formed as the filled via.

Moreover, a remaining portion of the multilayer wiring layer 223 and the interlayer insulating film 240 is formed on the second substrate 210 in which the through-hole via 250 is formed by using CVD, sputtering, plating or the like. Furthermore, the connecting terminal 230 is further formed on an uppermost multilayer wiring layer 223. With this arrangement, the second chip 200 is formed. Note that the multilayer wiring layer 223 and the connecting terminal 230 may be formed by using copper or the like. Furthermore, the interlayer insulating film 240 may be formed by using silicon oxide, silicon nitride, or the like.

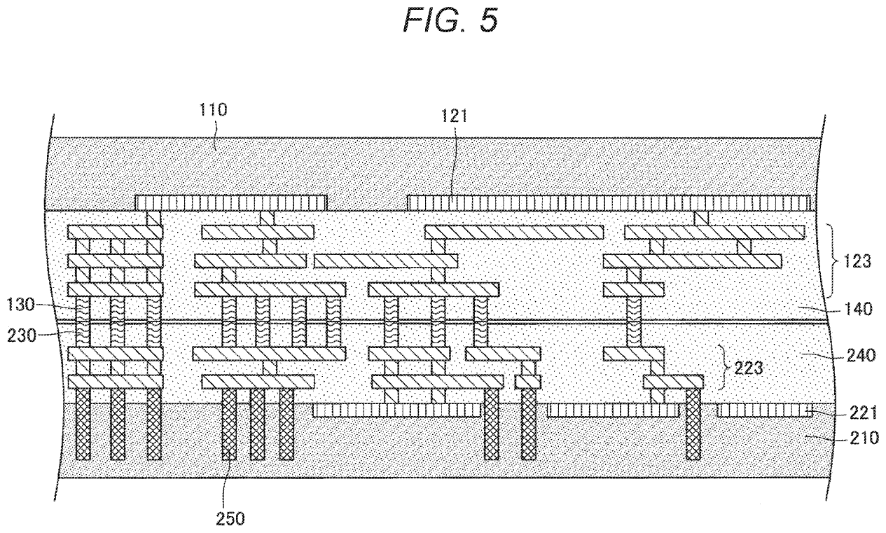

Subsequently, as illustrated in FIG. 5, the second chip 200 is bonded to the first chip 100.

Specifically, the first chip 100 is bonded to the second chip 200 so that the interlayer insulating film 140 and the interlayer insulating film 240 face each other. At that time, by applying a wafer alignment technology in the semiconductor manufacturing process, it is possible to control the alignment error between the connecting terminals 130 and 230 to several μm or smaller. With this arrangement, the connecting terminals 130 and 230 are electrically connected to each other by metal-metal bonding.

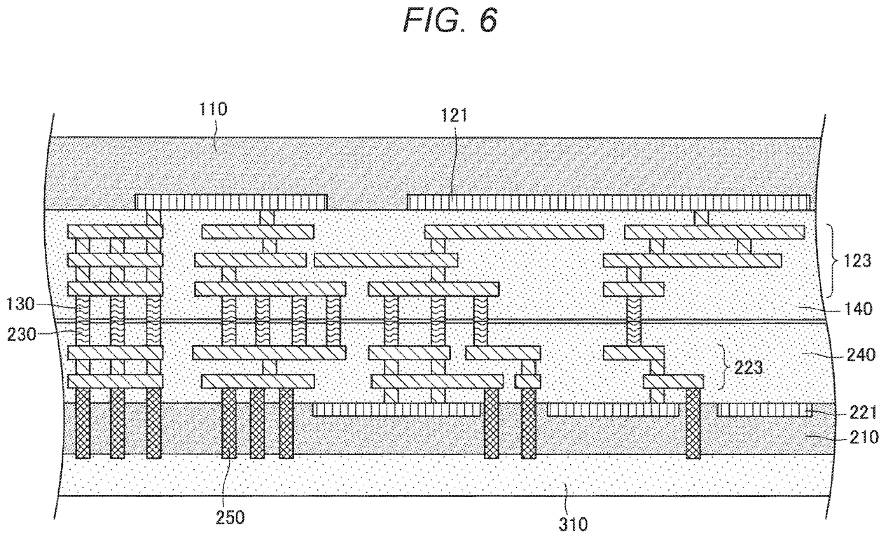

Next, as illustrated in FIG. 6, after thinning the second substrate 210 by back grinding, a protecting tape 310 is adhered to one surface of the second substrate 210.

Specifically, after the second substrate 210 is thinned by back grinding from a side of a surface opposed to a surface bonded to the first chip 100, this is subjected to mirror surface processing, so that the through-hole via 250 formed inside the second substrate 210 is exposed. At that time, since the through-hole via 250 is harder and less likely to be ground than the second substrate 210, the second substrate 210 is ground more than the through-hole via 250. With this arrangement, the through-hole via 250 is exposed to protrude from the second substrate 210. Note that the protruding amount of the through-hole via 250 from the second substrate 210 may be, for example, about 1 μm to 9 μm.

Thereafter, in order to protect the second substrate 210 and the through-hole via 250, the protecting tape 310 is adhered to the back-ground surface. The protecting tape 310 may be formed by using, for example, a resin or the like having mechanical strength and heat resistance which may withstand the manufacturing process of the semiconductor device 300. Furthermore, since the protecting tape 310 is removed after the semiconductor device 300 is formed, for example, this is preferably provided so as to be removable.

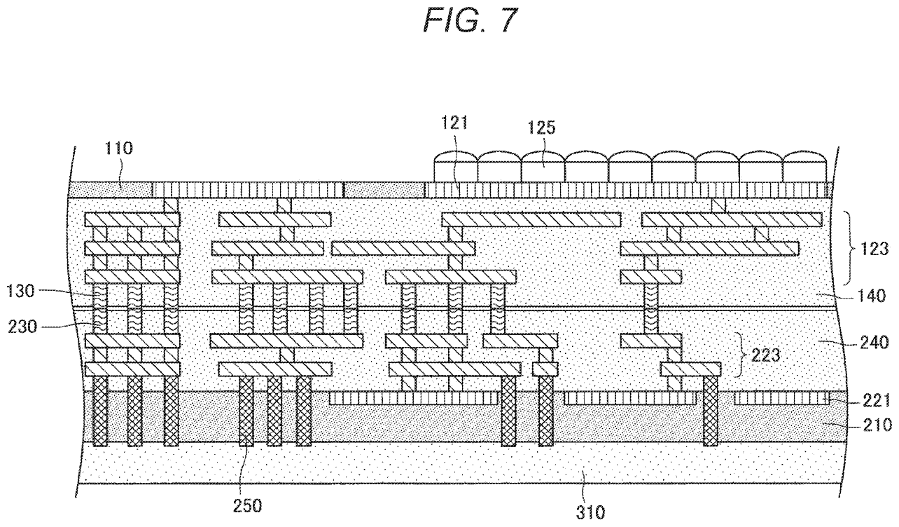

Moreover, as illustrated in FIG. 7, after thinning the first substrate 110 by back grinding, the optical element 125 is formed on one surface of the first substrate 110.

Specifically, after the first substrate 110 is thinned from a side of a surface opposed to a surface bonded to the second chip 200 by back grinding, this is subjected to mirror surface processing. Thereafter, the optical element 125 including the pixel separating film, the light shielding film, the color filter, the microlens, and the protecting film is formed on the first substrate 110 so as to correspond to the sensor element included in the first element unit 121.

Thereafter, the protecting tape 310 is removed, so that the semiconductor device 300 according to this embodiment as illustrated in FIG. 1 is formed.

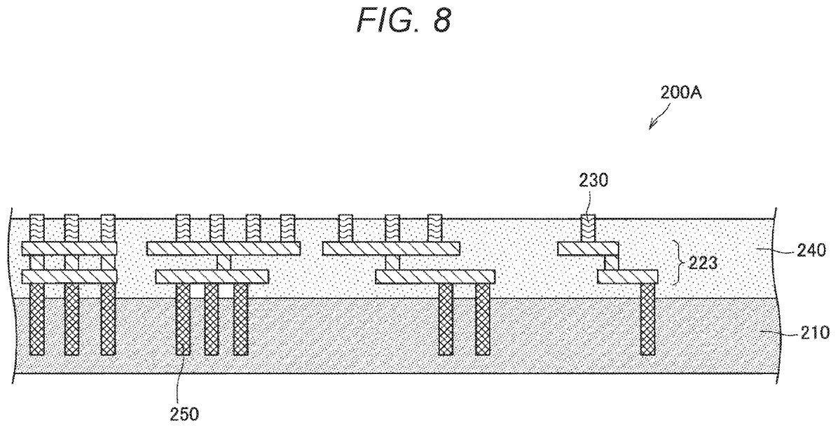

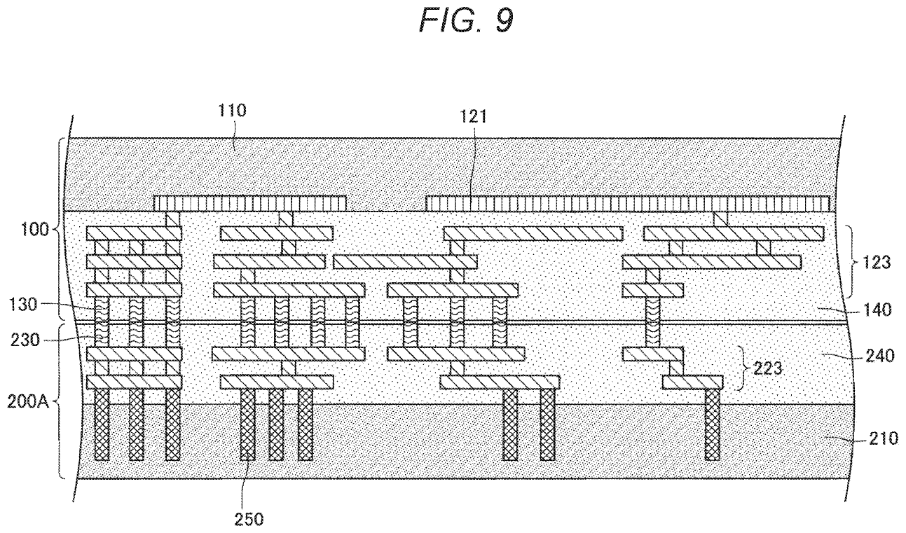

Note that, in the above-described manufacturing method, it is also possible to use a second chip 200A without the second element unit 221 provided. Such a case is described with reference to FIGS. 8 and 9. FIG. 8 is a cross-sectional view illustrating the second chip 200A without the second element unit 221 provided. Furthermore, FIG. 9 is a cross-sectional view illustrating a configuration in which the second chip 200A illustrated in FIG. 8 is bonded to the first chip 100.

As illustrated in FIG. 8, the second chip 200A without the second element unit 221 provided may also be prepared.

Specifically, one layer of the interlayer insulating film 240 is formed on the second substrate 210 which is the silicon substrate, and then etching is performed to form the opening for forming the through-hole via 250 in the second substrate 210. At that time, since the second element unit 221 is not formed in the second substrate 210, the position of the opening to be formed may be determined in consideration of only the arrangement of the terminal of the printed wiring board on which the semiconductor device 300 is mounted.

Subsequently, the insulating layer 241 is formed within the opening formed in the second substrate 210. Here, the insulating layer 241 is formed by the high-temperature process such as thermal oxidation of the second substrate 210 or deposition of silicon oxide in order to further improve the electric insulation.

Next, the barrier metal layer 251 is uniformly formed on the entire surface of the second substrate 210 using sputtering, and then a seed layer formed by using copper is formed on the barrier metal layer 251 using sputtering. Moreover, by growing the seed layer by electrolytic plating, the opening formed in the second substrate 210 is filled with copper, and the through-hole via 250 is formed. Thereafter, the barrier metal layer and the seed layer formed on the surface of the second substrate 210 are removed by CMP or the like.

Moreover, a remaining portion of the multilayer wiring layer 223 and the interlayer insulating film 240 are formed on the second substrate 210 on which the through-hole via 250 is formed by using CVD, sputtering, plating or the like. Furthermore, the connecting terminal 230 is further formed on an uppermost multilayer wiring layer 223. With this arrangement, the second chip 200A not provided with the second element unit 221 is formed. Note that the multilayer wiring layer 223 and the connecting terminal 230 may be formed by using copper or the like. Furthermore, the interlayer insulating film 240 may be formed by using silicon oxide, silicon nitride, or the like.

Moreover, as illustrated in FIG. 9, the first chip 100 may be bonded to the second chip 200A not provided with the second element unit 221.

Specifically, the first chip 100 may be bonded to the second chip 200A so that the interlayer insulating film 140 and the interlayer insulating film 240 face each other. At that time, metal-metal bonding may be performed such that the connecting terminal 130 and the connecting terminal 230 are electrically connected to each other by controlling the positions of the connecting terminals 130 and 230 using the wafer alignment technology in the semiconductor manufacturing process.

Hereinafter, the semiconductor device 300 according to this embodiment may be similarly manufactured at the steps described with reference to FIGS. 6 and 7 even in a case of using the second chip 200A without the second element unit 221 provided.

(2.2. Second Manufacturing Method)

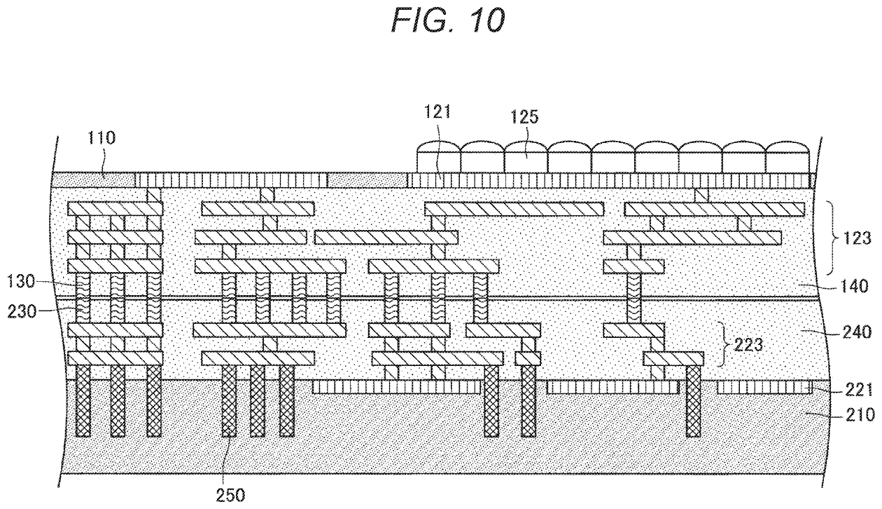

Subsequently, with reference to FIGS. 10 to 12, a second manufacturing method of the semiconductor device according to this embodiment is described. FIGS. 10 to 12 are cross-sectional views for illustrating each step of the second manufacturing method of the semiconductor device according to this embodiment.

Unlike the first manufacturing method, the second manufacturing method is a method of forming the semiconductor device 300 as a WLCSP capable of being directly mounted on the printed wiring board.

Steps of preparing the first chip 100 and the second chip 200 and bonding the second chip 200 to the first chip 100 are as those described with reference to FIGS. 3 to 5, so that the description is herein omitted.

Next, as illustrated in FIG. 10, after thinning the first substrate 110 by back grinding, the optical element 125 is formed on one surface of the first substrate 110.

Specifically, after the first substrate 110 is thinned from a side of a surface opposed to a surface bonded to the second chip 200 by back grinding, this is subjected to mirror surface processing. Thereafter, the optical element 125 including the pixel separating film, the light shielding film, the color filter, the microlens, and the protecting film is formed on the first substrate 110 so as to correspond to the sensor element included in the first element unit 121.

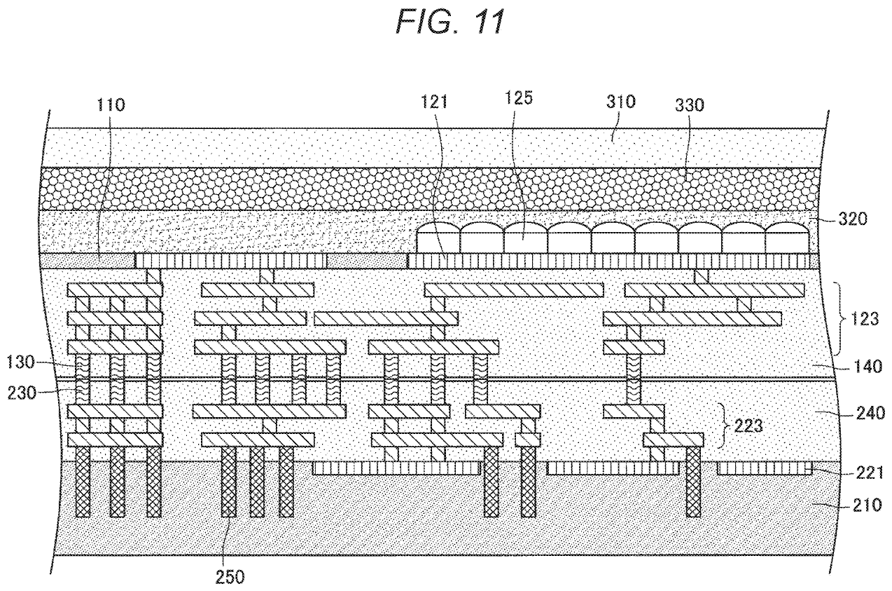

Subsequently, as illustrated in FIG. 11, a resin layer 320 and a protecting glass 330 are formed on the first substrate 110, and the protecting tape 310 is further adhered thereto.

Specifically, after the resin layer 320 is formed by applying an organic resin on the surface on which the optical element 125 is formed of the first substrate 110, the protecting glass 330 having the same planar shape as that of the first substrate 110 is adhered thereto. Note that materials with high light transmissivity are preferably used as the organic resin forming the resin layer 320 and the glass forming the protecting glass 330 so as not to affect the light incident on the sensor element. Moreover, the protecting tape 310 is adhered to the protecting glass 330. The protecting tape 310 serves to protect the protecting glass 330 at a step of thinning the second substrate 210 in the latter stage.

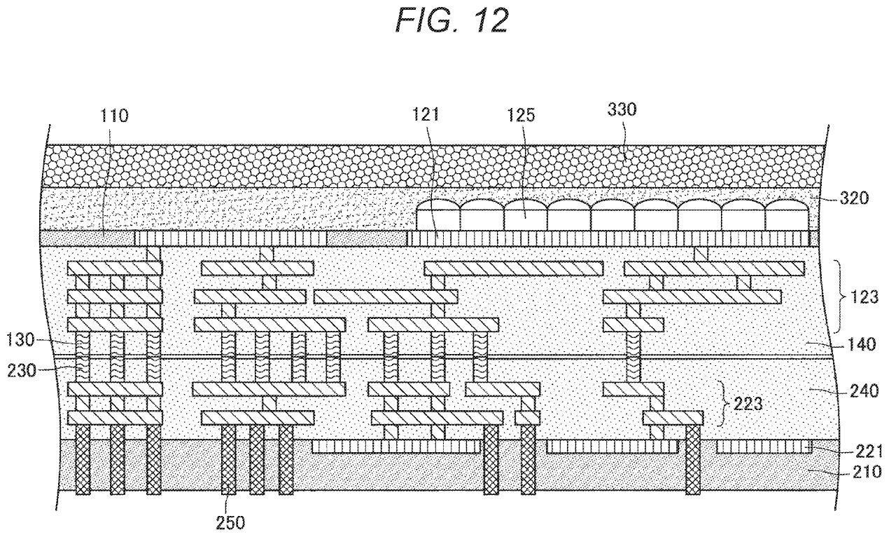

Next, as illustrated in FIG. 12, the second substrate 210 is thinned by back grinding to expose the through-hole via 250.

Specifically, after the second substrate 210 is thinned by back grinding from a side of a surface opposed to a surface bonded to the first chip 100, this is subjected to mirror surface processing, so that the through-hole via 250 formed inside the second substrate 210 is exposed. At that time, since the through-hole via 250 is harder and less likely to be ground than the second substrate 210, the second substrate 210 is ground more than the through-hole via 250. Therefore, the through-hole via 250 is exposed to protrude from the second substrate 210. Thereafter, the protecting tape 310 is removed to form the semiconductor device 300 according to this embodiment.

The semiconductor device 300 manufactured by the second manufacturing method may be directly mounted on the printed wiring board or the like after being cut into individual chips by dicing.

<3. Summary>

As described above, according to the semiconductor device 300 according to this embodiment, it is possible to improve alignment accuracy between the multilayer wiring layer 223 and the through-hole via 250 by forming the through-hole via 250 in advance in the second substrate 210. Therefore, the semiconductor device 300 may decrease a margin for the alignment error of the through-hole via 250, so that the through-hole via 250 may be further miniaturized.

Furthermore, according to the semiconductor device 300 according to this embodiment, the through-hole via 250 may be formed in the second chip 200 before the first chip 100 including the sensor element weak against heat is bonded to the second chip 200. With this arrangement, since the insulating layer 241 provided between the through-hole via 250 and the second substrate 210 may be formed by the high-temperature process, the electric insulation between the through-hole via 250 and the second substrate 210 may be improved.

Moreover, according to the semiconductor device 300 according to this embodiment, since the through-hole via 250 may be formed into the columnar shape or in the inverted tapered shape as the filled via, the conductivity of the through-hole via 250 may be improved and the mechanical strength of the semiconductor device 300 may be improved.

Although the preferred embodiment of the present disclosure is described above in detail with reference to the attached drawings, the technical scope of the present disclosure is not limited to such examples. It is clear that one of ordinary skill in the technical field of the present disclosure may conceive of various modifications and corrections within the scope of the technical idea recited in claims and it is understood that they also naturally belong to the technical scope of the present disclosure.

Furthermore, the effects described in this specification are merely illustrative or exemplary, and are not limiting. That is, the technology according to the present disclosure may exhibit other effects obvious to those skilled in the art from the description of this specification together with or in place of the above-described effects.

Note that the following configuration is also within the technical scope of the present disclosure.

(1)

A semiconductor device provided with:

a first chip formed by stacking a first substrate and a first wiring layer, the first chip including a sensor element;

a second chip formed by stacking a second substrate and a second wiring layer, the second chip bonded to the first chip such that the first wiring layer faces the second wiring layer; and

at least one or more through-hole vias electrically connected to the second wiring layer and penetrating the second substrate to protrude from a surface of the second chip opposed to a surface on which the first chip is stacked.

(2)

The semiconductor device according to (1) described above,

in which the through-hole via is a filled via an inside of which is filled.

(3)

The semiconductor device according to (2) described above,

in which a cross-sectional area of the through-hole via on one surface on which the second wiring layer is stacked of the second substrate is the same as or larger than a cross-sectional area of the through-hole via on the other surface of the second substrate opposed to the one surface.

(4)

The semiconductor device according to any one of (1) to (3) described above,

in which one or a plurality of the through-hole vias is provided for each signal line provided in the second wiring layer.

(5)

The semiconductor device according to any one of (1) to (4) described above,

in which an insulating layer is provided between the through-hole via and the second substrate.

(6)

The semiconductor device according to (5) described above,

in which a barrier metal layer is provided on a surface of the through-hole via in contact with the insulating layer.

(7)

The semiconductor device according to any one of (1) to (6) described above,

in which the first wiring layer is electrically connected to the second wiring layer via connecting terminals protruding from chip surfaces.

(8)

The semiconductor device according to any one of (1) to (7) described above,

in which the second chip includes an active circuit electrically connected to the sensor element.

(9)

The semiconductor device according to any one of (1) to (8) described above,

in which the sensor element is an image sensor.

(10)

A manufacturing method of a semiconductor device provided with:

a step of forming a first chip including a sensor element by stacking a first substrate and a first wiring layer;

a step of forming a second chip by stacking a second substrate and a second wiring layer;

a step of forming at least one or more through-hole vias electrically connecting to the second wiring layer and stretching in a thickness direction of the second substrate; and

a step of bonding the first chip to the second chip such that the first wiring layer faces the second wiring layer.

(11)

The manufacturing method of the semiconductor device according to (10) described above, further provided with:

a step of exposing the through-hole via by polishing a surface of the second chip opposed to a surface on which the first chip is stacked after the first chip is bonded to the second chip.

### REFERENCE SIGNS LIST

100 First chip
110 First substrate
121 First element unit
123 Multilayer wiring layer
125 Optical element
130 Connecting terminal
140 Interlayer insulating film
200 Second chip
210 Second substrate
221 Second element unit
223 Multilayer wiring layer
230 Connecting terminal
240 Interlayer insulating film
241 Insulating layer
250 Through-hole via
251 Barrier metal layer
300 Semiconductor device

1. A semiconductor device comprising:
a first chip formed by stacking a first substrate and a first wiring layer, the first chip including a sensor element;
a second chip formed by stacking a second substrate and a second wiring layer, the second chip bonded to the first chip such that the first wiring layer faces the second wiring layer; and
at least one or more through-hole vias electrically connected to the second wiring layer and penetrating the second substrate to protrude from a surface of the second chip opposed to a surface on which the first chip is stacked.

2. The semiconductor device according to claim 1,
wherein the through-hole via is a filled via an inside of which is filled.

3. The semiconductor device according to claim 2,
wherein a cross-sectional area of the through-hole via on one surface on which the second wiring layer is stacked of the second substrate is same as or larger than a cross-sectional area of the through-hole via on another surface of the second substrate opposed to the one surface.

4. The semiconductor device according to claim 1,
wherein one or a plurality of the through-hole vias is provided for each signal line provided in the second wiring layer.

5. The semiconductor device according to claim 1,
wherein an insulating layer is provided between the through-hole via and the second substrate.

6. The semiconductor device according to claim 5,
wherein a barrier metal layer is provided on a surface of the through-hole via in contact with the insulating layer.

7. The semiconductor device according to claim 1,
wherein the first wiring layer is electrically connected to the second wiring layer via connecting terminals protruding from chip surfaces.

8. The semiconductor device according to claim 1,
wherein the second chip includes an active circuit electrically connected to the sensor element.

9. The semiconductor device according to claim 1,
wherein the sensor element is an image sensor.

10. A manufacturing method of a semiconductor device, the method comprising:
a step of forming a first chip including a sensor element by stacking a first substrate and a first wiring layer;
a step of forming a second chip by stacking a second substrate and a second wiring layer;
a step of forming at least one or more through-hole vias electrically connecting to the second wiring layer and stretching in a thickness direction of the second substrate; and
a step of bonding the first chip to the second chip such that the first wiring layer faces the second wiring layer.

11. The manufacturing method of the semiconductor device according to claim 10, further comprising
a step of exposing the through-hole via by polishing a surface of the second chip opposed to a surface on which the first chip is stacked after the first chip is bonded to the second chip.
